(19) United States
(12) Patent Application Publication
(10) Pub. No.: US 2025/0210370 A1
(43) Pub. Date: Jun. 26, 2025

(54) ETCHING METHOD AND PLASMA PROCESSING APPARATUS

(71) Applicant: Tokyo Electron Limited, Tokyo (JP)

(72) Inventors: Fumiya TAKATA, Taiwan (CN); Shinya MORIKITA, Miyagi (JP); Kota OIKAWA, Miyagi (JP); Natsuki NIIKURA, Miyagi (JP)

(73) Assignee: Tokyo Electron Limited, Tokyo (JP)

(21) Appl. No.: 19/074,598

(22) Filed: Mar. 10, 2025

Related U.S. Application Data
(63) Continuation of application No. PCT/JP2024/031743, filed on Sep. 4, 2024.

(30) Foreign Application Priority Data
Sep. 8, 2023 (JP) 2023-145735

(51) Int. Cl. H01L 21/311; H01J 37/32

(52) U.S. Cl. CPC H01L 21/31116; H01J 37/32174; H01L 21/31144; H01J 2237/334

(57) ABSTRACT

An etching method includes: (a) preparing a substrate on a substrate support disposed in a chamber, wherein the substrate includes a plurality of first regions and at least one second region disposed between the first regions in a plan view, wherein the substrate includes a first film containing silicon and nitrogen, wherein the first film is disposed in the first regions and includes a recess in the at least one second region, and wherein a second film is disposed in the recess; (b) supplying a processing gas, which includes a first gas including metal and fluorine and a second gas capturing active species including fluorine, into the chamber; and (c) while (b) is performed, selectively etching the second film with respect to the first film in at least the recess by generating plasma from the processing gas by using a source radio frequency signal having a first frequency.

### CROSS-REFERENCE TO RELATED APPLICATIONS

The application is a Bypass Continuation Application of PCT International Application No. PCT/JP2024/031743, filed on Sep. 4, 2024 and designating the United States, the international application being based upon and claiming the benefit of priority from Japanese Patent Application No. 2023-145735, filed on Sep. 8, 2023, the entire content of each are incorporated herein by reference.

### TECHNICAL FIELD

The present disclosure relates to an etching method and a plasma processing apparatus.

### BACKGROUND

Patent Document 1 discloses an etching method as a technique of selectively etching a first region made of silicon oxide with respect to a second region made of silicon nitride.

### PRIOR ART DOCUMENT

### Patent Document

Patent Document 1: Japanese Patent Laid-Open Publication No. 2016-157793

### SUMMARY

An exemplary embodiment of the present disclosure provides an etching method performed in a plasma processing apparatus including a chamber. The etching method includes: (a) preparing a substrate on a substrate support disposed in the chamber, wherein the substrate includes a plurality of first regions and at least one second region disposed between the first regions in a plan view of the substrate, wherein the substrate includes a first film containing silicon and nitrogen, wherein the first film is disposed in the plurality of first regions and includes a recess in the at least one second region, and wherein a second film is disposed in the recess; (b) supplying a processing gas, which includes a first gas including metal and fluorine and a second gas capturing active species including fluorine, into the chamber; and (c) while (b) is performed, selectively etching the second film with respect to the first film in at least the recess by generating plasma from the processing gas by using a source radio frequency (RF) signal having a first frequency.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating a configuration example of a plasma processing system.

FIG. 2 is a view illustrating a configuration example of a capacitively coupled plasma processing apparatus.

FIG. 3 is a flowchart of an etching method according to an exemplary embodiment.

FIG. 4 is a view illustrating an example of a cross-sectional structure of a substrate W prepared in step ST1.

FIG. 5 is a view illustrating an example of a cross-sectional structure of the substrate W after a portion of a silicon oxide film is etched in step ST1.

FIG. 6 is a timing chart illustrating an example of a source RF signal HF, a bias RF signal MF, and a bias RF signal LF in step ST32.

FIG. 7 is a timing chart illustrating an example of a source RF signal HF, a bias RF signal MF, and a bias RF signal LF in step ST32.

FIG. 8 is a timing chart illustrating an example of a source RF signal HF, a bias RF signal MF, and a bias RF signal LF in step ST32.

FIG. 9 is a timing chart illustrating an example of a source RF signal HF, a bias RF signal MF, and a bias RF signal LF in step ST32.

FIG. 10 is a timing chart illustrating an example of a source RF signal HF, a bias RF signal MF, and a bias RF signal LF in step ST32.

FIG. 11 is a timing chart illustrating an example of a source RF signal HF, a bias RF signal MF, and a bias RF signal LF in step ST32.

FIG. 12 is a timing chart illustrating an example of a source RF signal HF, a bias RF signal MF, and a bias RF signal LF in step ST32.

FIG. 13 is a timing chart illustrating an example of a source RF signal HF, a bias RF signal MF, and a bias RF signal LF in step ST32.

FIG. 14 is a view illustrating an example of a cross-sectional structure of the substrate W on which a processing in step ST3 is performed.

FIG. 15 is a view illustrating an example of a cross-sectional structure of the substrate W on which a processing in step ST3 is performed.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

An exemplary embodiment provides an etching method performed in a plasma processing apparatus including a chamber. The etching method includes: (a) preparing a substrate on a substrate support disposed in the chamber, wherein the substrate includes a plurality of first regions and at least one second region between the first regions in a plan view of the substrate, wherein the substrate includes a first film including silicon and nitrogen, wherein the first film is disposed in the plurality of first regions and includes a recess in the at least one second region, and wherein a second film is disposed in the recess; (b) supplying a processing gas, which includes a first gas including metal and fluorine and a second gas capturing active species including fluorine, into the chamber; and (c) while (b) is performed, selectively etching the second film with respect to the first film in at least the recess by supplying a source radio frequency (RF) signal having a first frequency to a counter electrode facing the substrate support and generating plasma from the processing gas.

In the exemplary embodiment, in (a), the second film may be further disposed on the first film, the substrate may further include a mask including a first opening and disposed on the second film, and the mask may be disposed on the second film such that the first opening overlaps with the recess in a plan view of the substrate.

In the exemplary embodiment, in (a), the mask may include a second opening having an opening area larger than that of the first opening, the mask may be disposed on the second film such that the second opening overlaps with the recess in a plan view of the substrate, and the number of the recess overlapping with the first opening may be smaller than that of the recess overlapping with the second opening.

In the exemplary embodiment, the second film may be a film including silicon and oxygen.

In the exemplary embodiment, the first gas may be a tungsten-containing gas or a molybdenum-containing gas.

In the exemplary embodiment, the second gas may be a hydrogen-containing gas.

In the exemplary embodiment, the hydrogen-containing gas may be hydrogen gas.

In the exemplary embodiment, the second gas may be carbon monoxide gas.

In the exemplary embodiment, the processing gas may further include a carbon-containing gas.

In the exemplary embodiment, the carbon-containing gas may be a fluorocarbon gas.

In the exemplary embodiment, the carbon-containing gas may be a hydrofluorocarbon gas.

In the exemplary embodiment, (c) may include: (c1) generating the plasma by setting power of the source RF signal as a first power, and supplying a first bias signal as a second power to the substrate support; and (c2) after (c1), supplying the first bias signal as a third power higher than the second power to the substrate support.

In the exemplary embodiment, (c2) may further include setting the power of the source RF signal as a fourth power lower than the first power.

In the exemplary embodiment, the fourth power may be zero power.

In the exemplary embodiment, the second power may be zero power.

In the exemplary embodiment, in (c1), a second bias RF signal having a second frequency lower than the first frequency may be supplied as a fifth power to the substrate support, and in (c2), the second bias RF signal may be supplied as a sixth power lower than the fifth power to the substrate support.

In the exemplary embodiment, the first frequency of the source RF signal may be 60 MHz to 200 MHz.

In the exemplary embodiment, a frequency of the first bias signal may be a frequency not substantially contributing to the generation of the plasma.

In the exemplary embodiment, the frequency of the first bias signal may be 100 kHz to 800 kHz.

In the exemplary embodiment, the second frequency of the second bias RF signal may be 3 MHz to 40 MHz.

An exemplary embodiment provides an etching method performed in a plasma processing apparatus including a chamber. The etching method includes: (a) preparing a substrate on a substrate support disposed in the chamber, wherein the substrate includes a plurality of first regions and at least one second region between the first regions in a plan view of the substrate, wherein the substrate includes a first film including at least one selected from the group consisting of a SiN film, a SiON film, a SiC film, a SiOC film, and a boron nitride film, wherein the first film is disposed in the plurality of first regions and includes a recess in the at least one second region, and wherein a second film is disposed in the recess; (b) supplying a processing gas, which includes a first gas including metal and fluorine and a second gas capturing active species including fluorine, into the chamber; and (c) while (b) is performed, selectively etching the second film with respect to the first film in at least the recess by generating plasma from the processing gas by using a source radio frequency (RF) signal having a first frequency.

An exemplary embodiment provides a plasma processing apparatus including a chamber and a controller. In the plasma processing apparatus, the controller performs controls to execute: (a) preparing a substrate on a substrate support disposed in the chamber, wherein the substrate includes a plurality of first regions and at least one second region between the first regions in a plan view of the substrate, wherein the substrate includes a first film including silicon and nitrogen, wherein the first film is disposed in the plurality of first regions and includes a recess in the at least one second region, and wherein a second film is disposed in the recess; (b) supplying a processing gas, which includes a first gas including metal and fluorine and a second gas capturing fluorine radicals, into the chamber; and (c) while (b) is performed, etching the second film in at least the recess by generating plasma from the processing gas by using a source radio frequency (RF) signal having a first frequency.

Hereinafter, each embodiment of the present disclosure will be described in detail with reference to the accompanying drawings. In each drawing, the same or similar elements are designated by the same reference numerals, and duplicate description will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the illustrated ratio.

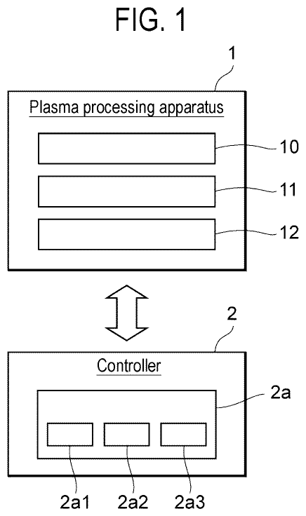

FIG. 1 is a view illustrating a configuration example of a plasma processing system. In an embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 includes at least one gas supply port for supplying at least one processing gas into the plasma processing space and at least one gas discharge port for discharging a gas from the plasma processing space. The gas supply port is connected to a gas supply 20 which will be described later, and the gas discharge port is connected to an exhaust system 40 which will be described later. The substrate support 11 is disposed in the plasma processing space, and has a substrate support surface for supporting a substrate.

The plasma generator 12 is configured to generate plasma from at least one processing gas supplied into the plasma processing space. The plasma generated in the plasma processing space may be capacitively coupled plasma (CCP), inductively coupled plasma (ICP), electron-cyclotron-resonance (ECR) plasma, helicon wave plasma (HWP), surface wave plasma (SWP), or the like. In addition, various types of plasma generators including an alternating current (AC) plasma generator and a direct current (DC) plasma generator may be used. In an embodiment, an AC signal (AC power) used in the AC plasma generator has a frequency within a range of 100 kHz to 10 GHz. Therefore, the AC signal includes a radio frequency (RF) signal and a microwave signal. In an embodiment, the RF signal has a frequency within a range of 100 kHz to 150 MHz.

The controller 2 processes computer-executable commands that cause the plasma processing apparatus 1 to perform various processes described in the present disclosure. The controller 2 may be configured to control individual components of the plasma processing apparatus 1 to perform the various processes described herein. In an embodiment, a part or an entirety of the controller 2 may be included in the plasma processing apparatus 1. The controller 2 may include a processor 2a1, a storage 2a2, and a communication interface 2a3. The controller 2 is implemented by, for example, a computer 2a. The processor 2al may be configured to perform various control operations by reading a program from the storage 2a2 and executing the read program. This program may be stored in the storage 2a2 in advance, or may be acquired via a medium when necessary. The acquired program is stored in the storage 2a2, and read from the storage 2a2 and executed by the processor 2a1. The medium may be various storage media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or any combination thereof. The communication interface 2a3 may communicate with the plasma processing apparatus 1 via a communication line such as a local area network (LAN).

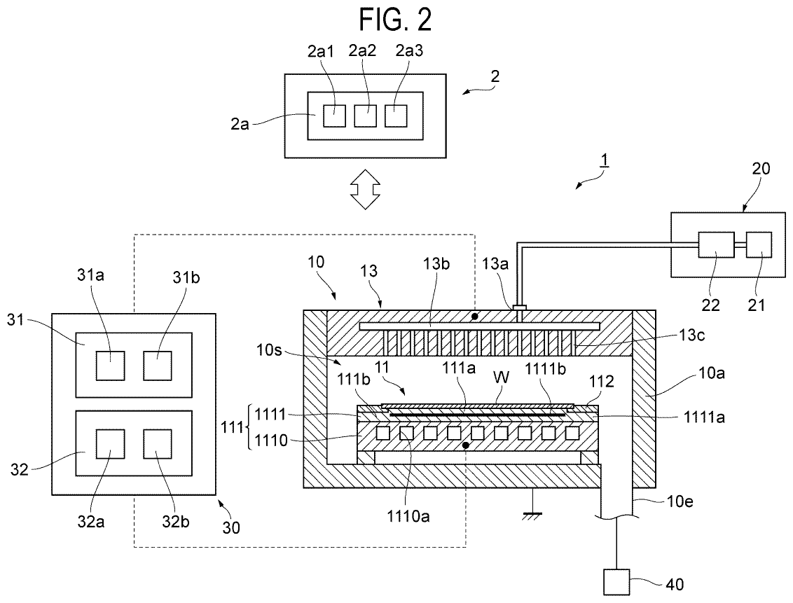

Hereinafter, a configuration of a capacitively coupled plasma processing apparatus as an example of the plasma processing apparatus 1 will be described. FIG. 2 is a view illustrating a configuration example of a capacitively coupled plasma processing apparatus.

The capacitively coupled plasma processing apparatus 1 includes the plasma processing chamber 10, the gas supply 20, a power supply 30, and the exhaust system 40. In addition, the plasma processing apparatus 1 includes the substrate support 11 and a gas introducer. The gas introducer is configured to introduce at least one processing gas into the plasma processing chamber 10. The gas introducer includes a showerhead 13. The substrate support 11 is disposed in the plasma processing chamber 10. The showerhead 13 is disposed above the substrate support 11. In an embodiment, the showerhead 13 constitutes at least a portion of a ceiling of the plasma processing chamber 10. The plasma processing chamber 10 has a plasma processing space 10s, which is defined by the showerhead 13, a sidewall 10a of the plasma processing chamber 10, and the substrate support 11. The plasma processing chamber 10 is grounded. The showerhead 13 and the substrate support 11 are electrically insulated from a housing of the plasma processing chamber 10.

The substrate support 11 includes a main body 111 and a ring assembly 112. The main body 111 has a central region 111a for supporting the substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductor. The conductor of the base 1110 may function as a lower electrode. The electrostatic chuck 1111 is disposed on the base 1110. The electrostatic chuck 1111 includes a ceramic 1111a and an electrostatic electrode 1111b disposed inside the ceramic 1111a. The ceramic 1111a includes the central region 111a. In an embodiment, the ceramic 1111a also includes the annular region 111b. In addition, another member surrounding the electrostatic chuck 1111, such as an annular electrostatic chuck or an annular insulator, may include the annular region 111b. In this case, the ring assembly 112 may be disposed on the annular electrostatic chuck or the annular insulator, or may be disposed on both the electrostatic chuck 1111 and the annular insulator. In addition, at least one RF/DC electrode coupled to an RF power supply 31 and/or a DC power supply 32, which will be described later, may be disposed inside the ceramic 1111a. In this case, the at least one RF/DC electrode functions as a lower electrode. When a bias RF signal and/or a DC signal, which will be described later, is supplied to the at least one RF/DC electrode, the RF/DC electrode is also referenced as a bias electrode. In addition, the conductor of the base 1110 and the at least one RF/DC electrode may function as a plurality of lower electrodes. In addition, the electrostatic electrode 1111b may function as a lower electrode. Therefore, the substrate support 11 includes at least one lower electrode.

The ring assembly 112 includes one or a plurality of annular members. In an embodiment, the one or plurality of annular members include one or a plurality of edge rings and at least one cover ring. The edge ring is made of a conductive material or an insulating material, and the cover ring is made of an insulating material.

In addition, the substrate support 11 may include a temperature adjustment module configured to adjust at least one of the electrostatic chuck 1111, the ring assembly 112, and the substrate to be a target temperature. The temperature adjustment module may include a heater, a heat transfer medium, a flow path 1110a, or any combination thereof. A heat transfer fluid such as brine and a gas flows through the flow path 1110a. In an embodiment, the flow path 1110a is formed inside the base 1110, and one or a plurality of heaters are disposed inside the ceramic 1111a of the electrostatic chuck 1111. In addition, the substrate support 11 may include a heat transfer gas supply configured to supply a heat transfer gas to a gap between a rear surface of the substrate W and the central region 111a.

The showerhead 13 is configured to introduce at least one processing gas from the gas supply 20 into the plasma processing space 10s. The showerhead 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. In addition, the showerhead 13 includes at least one upper electrode. The gas introducer may include one or a plurality of side gas injectors (SGIs) attached to one or a plurality of openings formed in the sidewall 10a, in addition to the showerhead 13.

The gas supply 20 may include at least one gas source 21 and at least one flow rate controller 22. In an embodiment, the gas supply 20 is configured to supply at least one processing gas to the showerhead 13 via the gas source 21 and the flow rate controller 22, which correspond thereto. Each flow rate controller 22 may include, for example, a mass flow controller or a pressure-controlled flow rate controller. In addition, the gas supply 20 may include at least one flow rate modulation device which modulates or pulses a flow rate of the at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. With this configuration, plasma is generated from the at least one processing gas supplied to the plasma processing space 10s. Therefore, the RF power supply 31 may function as at least a part of the plasma generator 12. In addition, by supplying a bias RF signal to at least one lower electrode, a bias potential is generated in the substrate W, and ions in the generated plasma can be attracted into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit, and configured to generate a source RF signal (source RF power) for plasma generation. In an embodiment, the source RF signal has a frequency within a range of 10 MHz to 150 MHz. In an embodiment, the first RF generator 31a may be configured to generate a plurality of source RF signals having different frequencies. The generated one or plurality of source RF signals are supplied to the at least one lower electrode and/or at least one upper electrode.

The second RF generator 31b is coupled to at least one lower electrode via at least one impedance matching circuit, and configured to generate a bias RF signal (bias RF power). A frequency of the bias RF signal may be equal to or different from the frequency of the source RF signal. In an embodiment, the bias RF signal has a frequency lower than that of the source RF signal. In an embodiment, the bias RF signal has a frequency within a range of 100 kHz to 60 MHz. In an embodiment, the second RF generator 31b may be configured to generate a plurality of bias RF signals having different frequencies. The generated one or plurality of bias RF signals are supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a first DC generator 32a and a second DC generator 32b. In an embodiment, the first DC generator 32a is connected to at least one lower electrode, and configured to generate a first DC signal. The generated first DC signal is applied to the at least one lower electrode. In an embodiment, the second DC generator 32b is connected to at least one upper electrode, and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may have a rectangular pulse waveform, a trapezoidal pulse waveform, a triangular pulse waveform, or any combination thereof. In an embodiment, a waveform generator for generating a sequence of voltage pulses from the DC signal is connected between the first DC generator 32a and the at least one lower electrode. Therefore, the first DC generator 32a and the waveform generator constitute a voltage pulse generator. When the second DC generator 32b and a waveform generator constitute a voltage pulse generator, the voltage pulse generator is connected to the at least one upper electrode. The voltage pulse may have positive polarity or negative polarity. In addition, the sequence of voltage pulses may include one or a plurality of positive voltage pulses and one or a plurality negative voltage pulses in one cycle. In addition, the first and second DC generators 32a and 32b may be provided in addition to the RF power supply 31, and the first DC generator 32a may be provided in place of the second RF generator 31b.

The exhaust system 40 may be connected to a gas discharge port 10e provided at, for example, a bottom of the plasma processing chamber 10. The exhaust system 40 may include a pressure regulating valve and a vacuum pump. An internal pressure of the plasma processing space 10s is adjusted by the pressure adjusting valve. The vacuum pump may include a turbo molecular pump, a dry pump, or any combination thereof.

### Example of Present Method

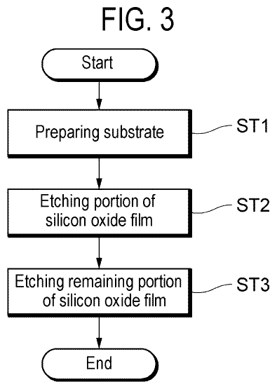

FIG. 3 is a flowchart illustrating an etching method (hereinafter, also referred to as “the present method”) according to an exemplary embodiment. The present method includes step ST1 of preparing a substrate, step ST2 of etching a portion of a silicon oxide film, and step ST3 of etching a remaining portion of the silicon oxide film. In an embodiment, a processing in each step may be performed in the plasma processing apparatus 1 (see FIGS. 1 and 2). In the following example, the controller 2 controls individual components of the capacitively coupled plasma processing apparatus 1 (see FIG. 2) to perform the present method.

### (Step ST1: Preparing Substrate)

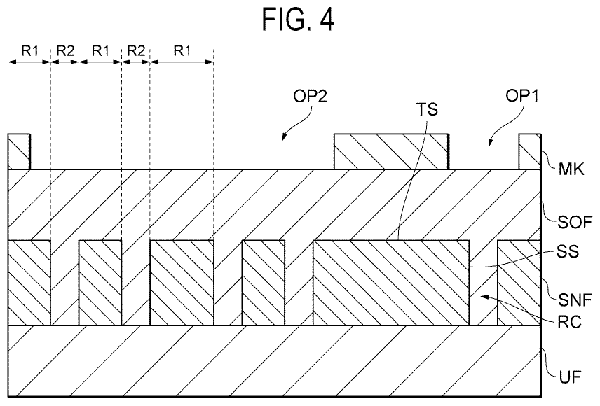

A substrate is prepared in step ST1. In step ST1, the substrate W is disposed in the central region 111a of the substrate support 11, and is held on the substrate support 11 by the electrostatic chuck 1111. FIG. 4 is a view illustrating an example of a cross-sectional structure of the substrate W prepared in step ST1. As illustrated in FIG. 4, the substrate W may include a base film UF, a silicon nitride film SNF, a silicon oxide film SOF, and a mask MK. The silicon nitride film SNF is an example of a film containing silicon and nitrogen. In addition, as the film containing silicon and nitrogen, a SiON film may be used in addition to the silicon nitride film. In addition, the substrate W may use at least one selected from the group consisting of a SiC film, a SiOC film, and a boron nitride film, instead of the film containing silicon and nitrogen or together with the film containing silicon and nitrogen. The silicon oxide film SOF is an example of a film containing silicon and oxygen. The substrate W may also be used in manufacturing a semiconductor device.

In an embodiment, the substrate W includes a plurality of regions R1 and a plurality of regions R2 in a plan view of the substrate W. The region R1 is an example of a first region. The region R2 is an example of a second region. The region R1 and the region R2 may be regions adjacent to each other. The plurality of regions R1 illustrated as being separated from one another in a cross-section shown in FIG. 4 may be continuous regions in another cross-section of the substrate W.

In an embodiment, the base film UF is a silicon wafer, or an organic film, a dielectric film, a metal film, a semiconductor film, or the like, which is formed on the silicon wafer. In an embodiment, the base film UF may include an etching stop film. As an example, the etching stop film may be a silicon nitride film.

In an embodiment, the base film UF may be configured by stacking a plurality of films. When the base film UF is configured by a plurality of films, the etching stop film may be formed in an uppermost layer of the base film UF. That is, the etching stop film may be disposed to be in contact with the silicon oxide film SOF.

The silicon nitride film SNF may be disposed on the base film UF. In an embodiment, the silicon nitride film SNF may be disposed in the plurality of regions R1 to include recesses RC in the plurality of regions R2 in a plan view of the substrate W. The recess RC may be an opening penetrating the silicon nitride film SNF. The recess RC may be a space defined by a side surface SS of the silicon nitride film SNF.

The silicon oxide film SOF is a film as an etching target in the present method. In the present method, the silicon oxide film SOF is a film selectively etched with respect the silicon nitride film SNF. In an embodiment, the silicon oxide film SOF may be disposed in at least the recess RC in a plan view of the substrate W. That is, in the region R2 or the recess RC, the silicon oxide film SOF may be disposed to be in contact with the side surface SS of the silicon nitride film SNF and the base film UF.

The silicon oxide film SOF may be disposed in both the region R1 and the second region R2. That is, as illustrated in FIG. 4, the silicon oxide film SOF may be disposed on the silicon nitride film SNF in the region R1. In addition, the silicon oxide film SOF may be disposed in the recess RC in the region R2, and may also be disposed above the recess RC. That is, the silicon oxide SOF may be disposed to cover the silicon nitride film SNF.

The mask MK includes an opening pattern for etching the silicon oxide SOF. The opening pattern may include a plurality of openings having different opening areas. In the example shown in FIG. 4, the mask MK includes an opening OP1 and an opening OP2 (hereinafter, the opening OP1 and the opening OP2 are collectively referred to as “openings OP”). The opening OP1 is an example of a first opening. The opening OP2 is an example of a second opening. The opening OP may have an arbitrary shape in a plan view of the substrate W. The shape may be, for example, a circle, an ellipse, a rectangle, a line, or any combination of one or more thereof. The mask MK has a plurality of side surfaces, and the plurality of side surfaces may define a plurality of openings OP. The plurality of openings OP may have line shapes and be arranged at a certain interval to form a line & space pattern.

In an embodiment, the region R1 and the region R2 may have a line shape at a portion at which the region R1 and the region R2 overlap with the opening OP. That is, the silicon nitride film SNF and the recesses RC may be configured to have a line & space pattern in a plan view of the substrate W. In an embodiment, the number of the recesses RC overlapping with the opening OP1 may be different from that of the recesses RC overlapping with the opening OP2. As an example, as illustrated in FIG. 4, the number of the recesses RC overlapping with the opening OP1 is 1, whereas the number of the recesses RC overlapping with the opening OP2 may be a plural number. In addition, the opening OP1 and the opening OP2 may have different opening areas. That is, aspect ratios of etching the silicon oxide film SOF in the opening OP1 and the opening OP2 may be different from each other.

A material included in the mask MK may be appropriately selected according to a type of a film to be etched. In an embodiment, the mask MK is made of a material having an etching rate, with respect to plasma generated in step ST3, lower than an etching rate of the film to be etched.

In an embodiment, the mask MK is a carbon-containing mask, a silicon-containing mask, or a metal-containing mask. The carbon-containing mask is, for example, an amorphous carbon (ACL) film, a spin-on carbon (SOC) film, or a photoresist film. An element such as boron, arsenic, or tungsten may be doped to the ACL film. The metal-containing mask may be a metal-containing film containing at least one metal selected from the group consisting of tungsten (W), molybdenum (Mo), and titanium (Ti), or a carbide thereof.

### (Step ST2: Etching Portion of Silicon Oxide Film)

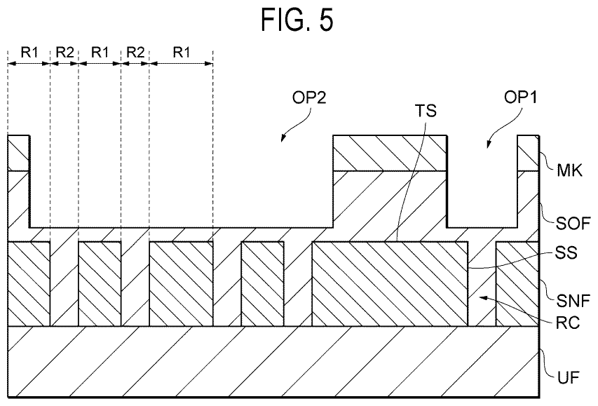

Subsequently, in step ST2, a portion of the silicon oxide film SOF is etched. FIG. 5 is a view illustrating an example of a cross-sectional structure of the substrate W after a portion of the silicon oxide film is etched in step ST2. As illustrated in FIG. 5, a portion of the silicon oxide film SOF in the opening OP is etched. In an embodiment, the silicon oxide film SOF may be etched to a degree that does not expose the silicon nitride film SNF in the opening OP. As an example, a thickness of the silicon oxide film SOF present on the silicon nitride film SNF in the opening OP may be 10 nm or less or 5 nm or less. In addition, as an example, the thickness of the silicon oxide film SOF present on the silicon nitride film SNF in the opening OP may be equal to or lower than 10% of that of the silicon oxide film SOF present on the silicon nitride film SNF in a region other than the opening OP. In addition, in an embodiment, the silicon oxide film SOF may be etched until the silicon nitride film SNF is exposed in the region R1.

In step ST2, the silicon oxide film SOF may be etched by plasma generated from a processing gas. In an embodiment, the processing gas may include a fluorine-containing gas. The fluorine-containing gas may be a fluorocarbon gas and/or a hydrofluorocarbon gas. The fluorocarbon gas may be, for example, at least one selected from the group consisting of CF₄ gas, C₂F₂ gas, C₂F₄ gas, C₃F₆ gas, C₃F₈ gas, C₄F₆ gas, C₄F₈ gas, and C₅F₈ gas. The hydrofluorocarbon gas may be, for example, at least one selected from the group consisting of CHF₃ gas, CH₂F₂ gas, CH₃F gas, C₂HF₅ gas, C₂H₂F₄ gas, C₂H₃F₃ gas, C₂H₄F₂ gas, C₃HF₇ gas, C₃H₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₆ gas, C₅H₂F₁₀ gas, and C₅H₃F₇ gas.

In addition, in step ST2, the plasma may be generated by supplying a source RF signal to an upper electrode or a lower electrode. The source RF signal supplied in step ST2 may be a continuous wave. When the source RF signal is supplied to the upper electrode or the lower electrode in a state in which the processing gas has been supplied into the plasma processing chamber 10, plasma is generated from the processing gas. In addition, active species in the plasma are attracted into the substrate W, so that a portion of the silicon oxide film SOF in the opening OP is etched by the active species. In addition, in step ST2, a bias signal may be supplied to the lower electrode.

### (Step ST3: Etching Remaining Portion of Silicon Oxide Film)

Subsequently, in step ST3, a remaining portion of the silicon oxide film SOF is etched. Step ST3 includes step ST31 of supplying a processing gas and step ST32 of supplying a source RF signal and a bias signal.

### (Step ST31: Supplying Processing Gas)

In the process ST31, a processing gas is supplied into the plasma processing chamber 10. Step ST31 and Step ST32 may be started simultaneously, or any one of step ST31 and step ST32 may be started earlier than the other of step ST31 and step ST32.

In step ST31, the processing gas may include a gas different from the gas included in the processing gas for etching a portion of the silicon oxide film SOF in steps ST2. In an embodiment, the processing gas in step ST31 includes a metal-containing gas. The metal-containing gas may be a tungsten-containing gas. The tungsten-containing gas may be a gas containing tungsten and halogen, and an example of the tungsten-containing gas is a WFₓCl_{y} gas (each of x and y is an integer of zero or more and six or less, and a sum of x and y is two or more and six or less). Specifically, the tungsten-containing gas may be a gas containing tungsten and fluorine, such as tungsten difluoride (WF₂) gas, tungsten tetrafluoride (WF₄) gas, tungsten pentafluoride (WF₅) gas, or tungsten hexafluoride (WF₆) gas, or may be a gas containing tungsten and chlorine, such as tungsten dichloride (WCl₂) gas, tungsten tetrachloride (WCl₄) gas, tungsten pentachloride (WCl₅), or tungsten hexachloride (WCl₆). Among the gases described above, the tungsten-containing gas may be at least one of the WF₆ gas and the WCl₆ gas. A flow rate of the tungsten-containing gas may be equal to or lower than 5 volume % of a total flow rate of the processing gas. In addition, the processing gas may include at least one of a titanium-containing gas, a ruthenium-containing gas, or a molybdenum-containing gas, instead of the tungsten-containing gas or in addition to the tungsten-containing gas.

In step ST31, the processing gas may further include a carbon-containing gas. The carbon-containing gas may be a fluorocarbon gas. The fluorocarbon gas may be, for example, at least one selected from the group consisting of CF₄ gas, C₂F₂ gas, C₂F₄ gas, C₃F₆ gas, C₃F₈ gas, C₄F₆ gas, C₄F₈ gas, and C₅F₈ gas. In an embodiment, the carbon-containing gas is a gas having a straight-chain structure with unsaturated bonds. Examples of such a gas may include C₃F₆ (hexafluoropropene) gas, C₄F₈ (octafluoro-1-butene, octafluoro-2-butene) gas, C₃H₂F₄ (1,3,3,3-tetrafluoropropene) gas, C₄H₂F₆ (trans-1,1,1,4,4,4-hexafluoro-2-butene) gas, C₄F₈O (pentafluoroethyl trifluorovinyl ether) gas, CF₃COF (1,2,2,2-tetrafluoroethane-1-on) gas, CHF₂COF (difluoroacetic acid fluoride) gas, and COF₂ (carbonyl fluoride) gas. In an embodiment, the carbon-containing gas may contain a halogen element other than fluorine, or may contain fluorine and a halogen element other than fluorine. Such a gas may be CᵢHⱼFₖXₗ. Here, X is halogen other than fluorine. In addition, i and I are integers of one or more, and j and k are integers of zero or more. The carbon-containing gas may include, for example, one or more gases among a CHⱼCₗ gas, a CFₖBrₗ gas, a CFₖRₗ gas, and a CᵢFₖClₗ gas. More specifically, the carbon-containing gas may be at least one selected from the group consisting of CHC13, CH₂Cl₂, and CF₂Br₂.

In step ST31, the processing gas may further include an inert gas. The inert gas may be a rare gas such as Ar gas, He gas, or Kr gas, and/or may be nitrogen gas.

In step ST31, the processing gas may further include a gas (scavenge gas) capturing active species including fluorine. The gas capturing the active species including fluorine may be an oxidizing gas or a reducing gas. As the oxidizing gas, carbon monoxide (CO) may be used. As the reducing gas, a hydrogen-containing gas such as hydrogen (H₂) may be used.

### (Step ST32: Supplying Source RF Signal and Bias Signal)

In step ST32, a source RF signal and a bias signal are supplied. Step ST32 is performed while step ST31 is performed, so that plasma is generated from the processing gas in the plasma processing chamber 10.

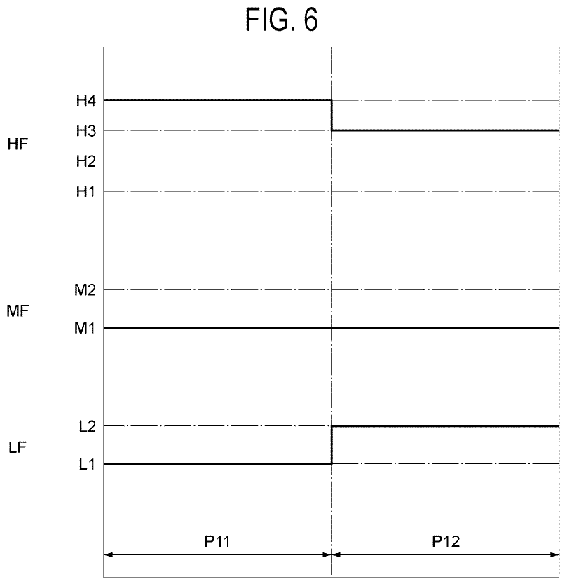

FIGS. 6 to 13 are timing charts illustrating examples of a source RF signal HF, a bias RF signal MF, and a bias RF signal LF. The source RF signal HF is an example of a source RF signal. The bias RF signal MF is an example of a second bias RF signal. The bias RF signal LF is an example of a first bias signal. In addition, the bias RF signal MF may have both functions of the source RF signal and the bias RF signal.

In FIGS. 6 to 13, the vertical axis represents a relative value of power of each signal. The power may be an effective value of power (hereinafter, also simply referred to as a “power”). In each drawing, powers H1 to H4, powers M1 and M2, and powers L1 and L2 represent magnitudinal relationships among power of the respective signals. Absolute and/or relative powers of the powers H1 to H4, the powers M1 and M2, and the powers L1 to L2 may be set arbitrarily. In addition, in each drawing, the vertical axis does not relatively represent a relationship of power among the signals.

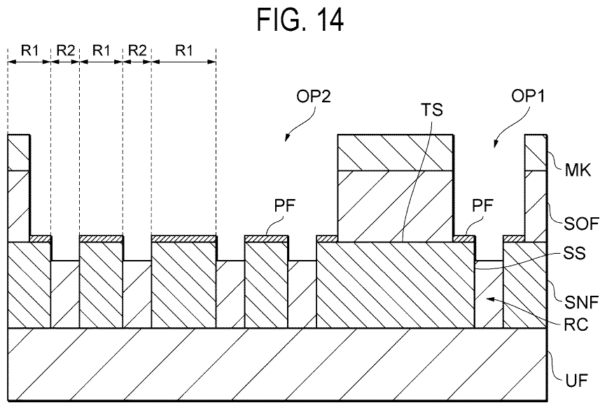

In addition, the power H1, the power M1, and the power L1 may be powers which do not substantially contribute to etching the silicon oxide film SOF and/or generating a protective film PF (see FIG. 14). As an example, the power H1, the power M1, and the power L1 may be zero power (0 W, substantially 0 W (including standby power as an example), or wattage of a degree that does not to substantially contribute to etching a film to be etched).

In FIGS. 6 to 13, the horizontal axis represents a time. In addition, a total time period illustrated in FIGS. 6 to 13 represents one cycle of step ST32. In addition, in each drawing, each of periods P11 and P12, periods P21 to P23, and periods P31 to P34 are illustrated to divide the cycle equally, but an absolute or relative time of each period may be set arbitrarily.

In the examples shown in FIGS. 6 to 13, a frequency of the source RF signal HF may be 60 MHz to 200 MHz. As an example, the frequency of the source RF signal HF is 100 MHz. In addition, a frequency of the bias RF signal MF may be 3 MHz to 40 MHz. As an example, the frequency of the bias RF signal MF is 13 MHz. In addition, a frequency of the bias RF signal LF may be a frequency which does not substantially contribute to generating plasma. As an example, the frequency may be 100 kHz to 800 kHz. In addition, the frequency of the bias RF signal LF may be 400 kHz.

In an embodiment, each cycle shown in FIGS. 6 to 13 is repeated, so that plasma is generated from the processing gas in step ST32. Accordingly, the silicon oxide film SOF is selectively etched with respect to the silicon nitride film SNF.

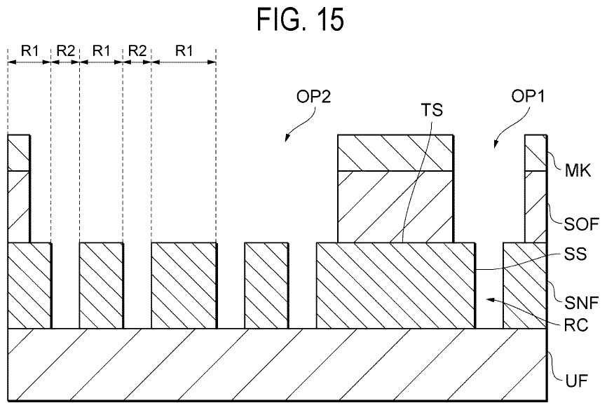

FIGS. 14 and 15 are views illustrating an example of cross-sectional structures of the substrate W for which the processing in step ST32 is performed. When the cycle shown in FIGS. 6 to 13 is repeated in step ST3, portions of the silicon oxide film SOF, which are exposed from the opening OP1 and the opening OP2, are further etched. Accordingly, as illustrated in FIG. 14, a top surface TS of the silicon nitride film SNF is exposed. When the etching the silicon oxide film SOF further proceeds in step ST3, the protective film PF is formed on the top surface TS of the silicon nitride film SNF and the silicon oxide film SOF is etched in the recess RC. When the etching the silicon oxide film SOF further proceeds in step ST3, the base film UF is exposed in the recess RC and the etching the silicon oxide film SOF ends. Hereinafter, details of step ST32 in each example of FIGS. 6 to 13 will be described.

In the example shown in FIG. 6, one cycle of step ST32 includes periods P11 and P12. First, in period P11, the source RF signal HF is supplied as the power H4 to the upper electrode. The upper electrode is an example of a counter electrode. In an embodiment, the power H4 may be 50 W to 2,000 W. As an example, the power H4 may be 200 W. In addition, in period P11, the bias RF signal MF is supplied as the power M1 to the lower electrode. In an embodiment, the power M1 may be 0 W to 20 W. As an example, the power M1 may be zero power. In addition, in period P11, the bias RF signal LF is supplied as the power L1 to the lower electrode. As an example, the power L1 may be zero power.

Subsequently, in period P12, the source RF signal HF is supplied as the power H3 to the upper electrode. In an embodiment, the power H3 may be 20 W to 500 W. As an example, the power H3 may be 150 W. In addition, in period P12, the bias RF signal MF is supplied as the power M1 to the lower electrode. In addition, in period P12, the bias RF signal LF is supplied as the power L2 to the lower electrode. In an embodiment, the power L2 may be 10 W to 150 W. As an example, the power L2 may be 75 W.

In the example shown in FIG. 6, periods P11 and P12 are repeated to generate plasma from the processing gas. In this example, in period P11, active species contributing to the etching the silicon oxide film SOF may be generated by the source RF signal HF. In addition, in period P12, the active species generated in period P11 are attracted into the substrate W by the bias RF signal LF, so that the silicon oxide film SOF is etched.

In addition, in period P11, active species for forming the protective film PF which will be described later may be generated by the source RF signal HF to form the protective film PF on the silicon nitride film SNF.

In the example shown in FIG. 6, when periods P11 and P12 are repeated and the etching the silicon oxide film SOF proceeds, the top surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in period P11. The active species may be active species generated from a carbon-containing gas. In an embodiment, the protective film PF may be formed by forming active sites on the surface of the silicon nitride film SNF and adsorbing another active species to the active sites. The active sites and the active species may be the active species generated in period P11.

As the example shown in FIG. 6, when the etching the silicon oxide film SOF further proceeds, the silicon oxide film SOF is further etched in the recess RC while the surface of the silicon nitride film SNF is protected by the protective film PF (see FIG. 15). As described above, the silicon oxide film SOF is selectively etched with respect to the silicon nitride film SNF.

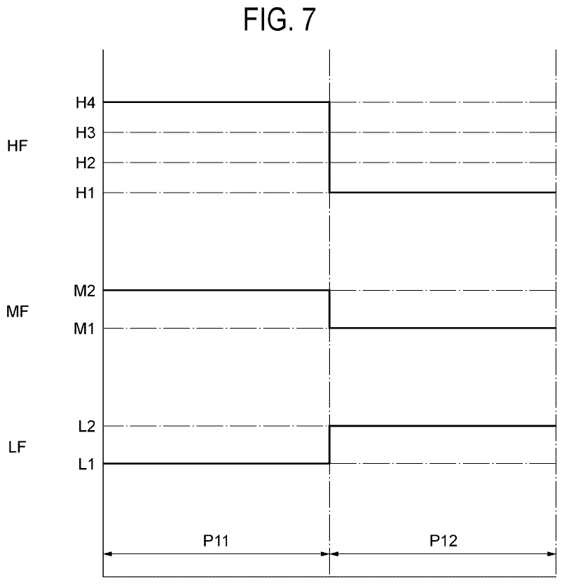

Next, the example shown in FIG. 7 will be described. In the example shown in FIG. 7, one cycle of step ST32 includes periods P11 and P12. First, in period P11, the source RF signal HF is supplied as the power H4 to the upper electrode. In an embodiment, the power H4 may be 50 W to 2,000 W. As an example, the power H4 may be 200 W. In addition, in period P11, the bias RF signal MF is supplied as the power M2 to the lower electrode. In an embodiment, the power M2 may be 10 W to 100 W. As an example, the power M2 may be zero power. In addition, in period P11, the bias RF signal is supplied as the power L1 to the lower electrode. As an example, the power L1 may be zero power.

Subsequently, in period P12, the source RF signal HF is supplied as the power H1 to the upper electrode. As an example, the power H1 may be 0 W. In addition, in period P12, the bias RF signal MF may be supplied as the power M1 to the lower electrode. As an example, the power M1 may be zero power. In addition, in period P12, the bias RF signal LF is supplied as the power L2 to the lower electrode. In an embodiment, the power L2 may be 10 W to 150 W. As an example, the power L2 may be 75 W.

In the example shown in FIG. 7, periods P11 and P12 are repeated to generate plasma from the processing gas in step ST32. In this example, in period P11, active species contributing to the etching the silicon oxide film SOF may be generated by the source RF signal HF. In addition, in period P12, the active species generated in period P11 are attracted into the substrate W by the bias RF signal LF and the silicon oxide film SOF is etched.

In addition, in period P11, active species for forming the protective film PF which will be described later may be generated by the source RF signal HF to form the protective film PF on the silicon nitride film SNF. In addition, by the bias RF signal MF, an amount of the active species for forming the protective film PF and/or a composition of the protective film PF may be controlled. As an example, at least a surface of the protective film PF may be modified by the active species generated by the bias RF signal MF.

In the example shown in FIG. 7, when periods P11 and P12 are repeated and the etching the silicon oxide film SOF proceeds, the top surface TS of the silicon nitride film SNF is exposed (see FIG. 14). When the surface of the silicon nitride film SNF is exposed, the protective film PF may be generated on the surface of the silicon nitride film SNF. In period P11, the protective film PF may be formed by the active species generated by the source RF signal HF. The active species may be active species generated from a carbon-containing gas. In an embodiment, the protective film PF may be formed by forming active sites on the surface of the silicon nitride film SNF and adsorbing another active species to the active sites. The active sites and the active species may be the active species generated in period P11.

In the example shown in FIG. 7, when the etching the silicon oxide film SOF further proceeds, the silicon oxide film SOF is further etched in the recess RC while the surface of the silicon nitride film SNF is protected by the protective film PF (see FIG. 15). As described above, the silicon oxide film SOF is selectively etched with respect to the silicon nitride film SNF.

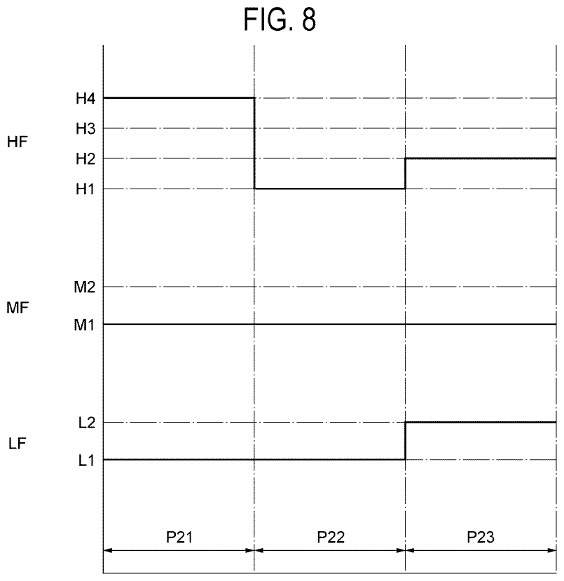

Next, the example shown in FIG. 8 will be described. In the example shown in FIG. 8, one cycle of step ST32 includes periods P21 to P23. First, in period P21, the source RF signal HF is supplied as the power H4 to the upper electrode. In an embodiment, the power H4 may be 50 W to 2,000 W. As an example, the power H4 may be 200 W. In addition, in period P21, the bias RF signal MF is supplied as the power M1 to the lower electrode. As an example, the power M1 may be zero power. In addition, in period P21, the bias RF signal LF is supplied as the power L1 to the lower electrode. As an example, the power L1 may be zero power.

Subsequently, in period P22, the source RF signal HF is supplied as the power H1 to the upper electrode. As an example, the power H1 may be 0 W. In addition, in period P22, the bias RF signal MF is supplied as the power M1 to the lower electrode. In addition, in period P22, the bias RF signal LF is supplied as the power L1 to the lower electrode.

Subsequently, in period P23, the source RF signal HF is supplied as the power H2 to the upper electrode. In an embodiment, the power H2 may be 20 W to 200 W. As an example, the power H2 may be 100 W. In addition, in period P23, the bias RF signal MF is supplied as the power M1 to the lower electrode. In addition, in period 23, the bias RF signal LF is supplied as the power L2 to the lower electrode. In embodiment, the power L2 may be 10 W to 150 W. As an example, the power L2 may be 75 W.

In the example shown in FIG. 8, periods P21 to P23 are repeated to generate plasma from the processing gas in step ST32. In this example, in period P21, active species contributing to the etching the silicon oxide film SOF may be generated by the source RF signal HF. In addition, in period P22, the power of the source RF signal HF is reduced. In addition, in period P23, the active species generated in period P21 are attracted into the substrate W by the bias RF signal LF and the silicon oxide film SOF is etched. In addition, in period 23, the source RF signal HF is supplied as the power H2 to the upper electrode to maintain the plasma generated in period P21.

In addition, in period P21, by the source RF signal HF, active species for forming the protective film RF which will be described later may generated to form the protective film RF on the silicon nitride film SNF.

In the example shown in FIG. 8, when periods P21 to P23 are repeated and the etching the silicon oxide film SOF proceeds, the top surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in period P21. The active species may be active species generated from a carbon-containing gas. In an embodiment, the protective film PF may be formed by forming active sites on the surface of the silicon nitride film SNF and adsorbing another active species to the active sites. The active sites and the active species may be the active species generated in period P21.

In the example shown in FIG. 8, when the etching the silicon oxide film SOF further proceeds, the silicon oxide film SOF is further etched in the recess RC while the surface of the silicon nitride film SNF is protected by the protective film PF (see FIG. 15). As described above, the silicon oxide film SOF is selectively etched with respect to the silicon nitride film SNF.

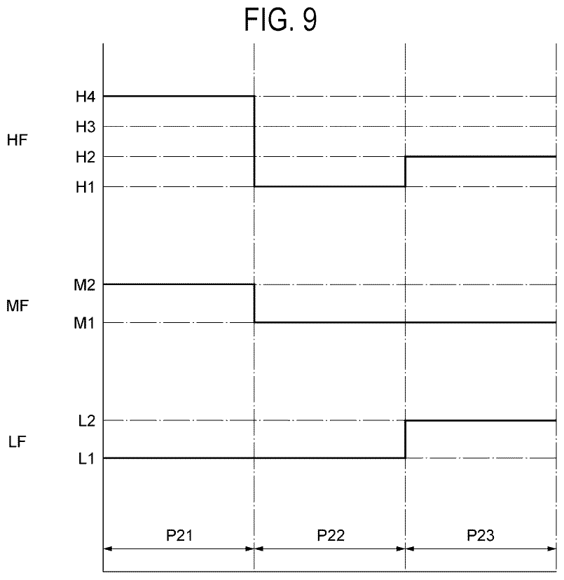

Next, the example shown in FIG. 9 will be described. In the example shown in FIG. 9, one cycle of step ST32 includes periods P21 to P23. First, in period P21, the source RF signal HF is supplied as the power H4 to the upper electrode. In an embodiment, the power H4 may be 50 W to 2,000 W. As an example, the power H4 may be 200 W. In addition, in period P21, the bias RF signal MF is supplied as the power M2 to the lower electrode. In an embodiment, the power M2 may be 10 W to 100 W. As an example, the power M2 may be 50 W. In addition, in period P21, the bias RF signal LF is supplied as the power L1 to the lower electrode. As an example, the power L1 may be zero power.

Subsequently, in period P22, the source RF signal HF is supplied as the power H1 to the upper electrode. As an example, the power H1 may be 0 W. In addition, in period P22, the bias RF signal MF is supplied as the power M1 to the lower electrode. In addition, in period P22, the bias RF signal LF is supplied as the power L1 to the lower electrode.

Subsequently, in period P23, the source RF signal HF is supplied as the power H2 to the upper electrode. In an embodiment, the power H2 may be 20 W to 200 W. As an example, the power H2 may be 100 W. In addition, in period P23, the bias RF signal MF is supplied as the power M1 to the lower electrode. In addition, in period P23, the bias RF signal LF is supplied as the power L2 to the lower electrode. In an embodiment, the power L2 may be 10 W to 150 W. As an example, the power L2 may be 75 W.

In the example shown in FIG. 9, periods P21 to P23 are repeated and plasma is generated from the processing gas in step ST32. In this example, in period P21, active species contributing to the etching the silicon oxide film SOF may be generated by the source RF signal HF. In addition, in period P22, the power of the source RF signal HF and the power of the bias RF signal MF are reduced. In addition, in period P23, the active species generated in period P21 are attracted into the substrate W by the bias RF signal LF and the silicon oxide film SOF is etched. In addition, the source RF signal HF is supplied as the power H2 to the upper electrode in the period P23 to maintain the plasma generated in period P21.

In addition, in period P21, active species for forming the protective film PF which will be described later may be generated by the source RF signal HF to form the protective film PF on the silicon nitride film SNF. In addition, by the bias RF signal MF, an amount of the active species for forming the protective film PF and/or a composition of the protective film PF may be controlled. As an example, at least a surface of the protective film PF may be modified by the active species generated by the bias RF signal MF.

In the example shown in FIG. 9, when periods P21 to P23 are repeated and the etching the silicon oxide film SOF proceeds, the top surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in period P21. The active species may be active species generated from a carbon-containing gas. In an embodiment, the protective film PF may be formed by forming active sites on the surface of the silicon nitride film SNF and adsorbing another active species to the active sites. The active sites and the active species may be the active species generated in period P21.

In the example shown in FIG. 9, when the etching the silicon oxide film SOF further proceeds, the silicon oxide film SOF is further etched in the recess RC while the surface of the silicon nitride film SNF is protected by the protective film PF (see FIG. 15). As described above, the silicon oxide film SOF is selectively etched with respect to the silicon nitride film SNF.

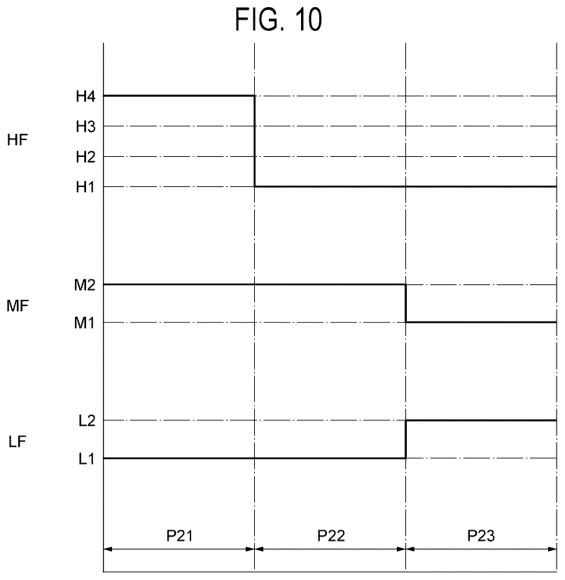

Next, the example shown in FIG. 10 will be described. In the example shown in FIG. 10, one cycle of step ST32 includes periods P21 to P23. First, in period P21, the source RF signal HF is supplied as the power H4 to the upper electrode. In an embodiment, the power H4 may be 50 W to 2,000 W. As an example, the power H4 may be 200 W. In addition, in period P21, the bias RF signal MF is supplied as the power M2 to the lower electrode. In an embodiment, the power M2 may be 10 W to 100 W. As an example, the power M2 may be 50 W. In addition, in period P21, the bias RF signal LF is supplied as the power L1 to the lower electrode. As an example, the power L1 may be zero power.

Subsequently, in period P22, the source RF signal HF is supplied as the power H1 to the upper electrode. As an example, the power H1 may be 0 W. In addition, in period P22, the bias RF signal MF is supplied as the power M2 to the lower electrode. In addition, in period P22, the bias RF signal LF is supplied as the power L1 to the lower electrode.

Subsequently, in period P23, the source RF signal HF is supplied as the power H1 to the upper electrode. As an example, the power H1 may be zero power. In addition, in period P23, the bias RF signal MF is supplied as the power M1 to the lower electrode. As an example, the power M1 may be zero power. In addition, in period P23, the bias RF signal LF is supplied as the power L2 to the lower electrode. In an embodiment, the power L2 may be 10 W to 150 W. As an example, the power L2 may be 75 W.

In the example shown in FIG. 10, periods P21 to P23 are repeated and plasma is generated from the processing gas in step ST32. In this example, in period P21, active species contributing to the etching the silicon oxide film SOF may be generated by the source RF signal HF. In addition, in period P22, the power of the source RF signal HF is reduced. In addition, in period P23, the active species generated in periods P21 and P22 are attracted into the substrate W by the bias RF signal LF and the silicon oxide film SOF is etched. In addition, the bias RF signal MF is supplied as the power M2 to the upper electrode in period P22 to maintain the plasma generated in period P21.

In addition, in period P21, active species for forming the protective film PF which will be described later may be generated by the source RF signal HF to form the protective film PF on the silicon nitride film SNF. In addition, by the bias RF signal MF, an amount of the active species for forming the protective film PF and/or a composition of the protective film PF may be controlled. As an example, at least a surface of the protective film PF may be modified by the active species generated by the bias RF signal MF.

In the example shown in FIG. 10, when periods P21 to P23 are repeated and the etching the silicon oxide film SOF proceeds, the top surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in period P21. The active species may be active species generated from a carbon-containing gas. In an embodiment, the protective film PF may be formed by forming active sites on the surface of the silicon nitride film SNF and adsorbing another active species to the active sites. The active sites and the active species may be the active species generated in periods P21 and P22.

In the example shown in FIG. 10, when the etching the silicon oxide film SOF further proceeds, the silicon oxide film SOF is further etched in the recess RC while the surface of the silicon nitride film SNF is protected by the protective film PF (see FIG. 15). As described above, the silicon oxide film SOF is selectively etched with respect to the silicon nitride film SNF.

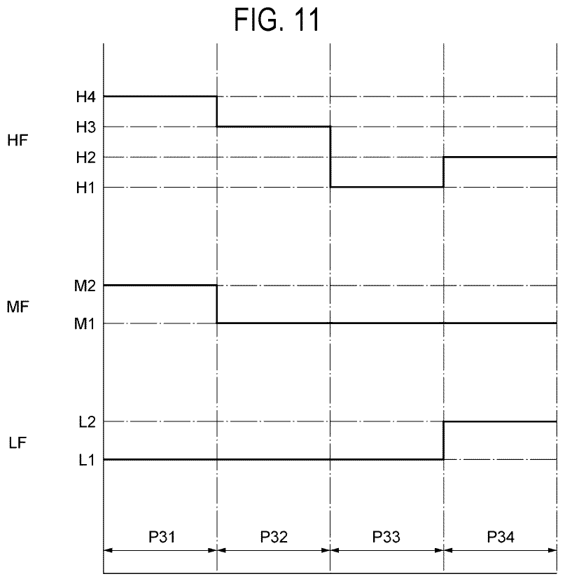

Next, the example shown in FIG. 11 will be described. In the example shown in FIG. 11, one cycle of step ST32 includes periods P31 to P34. First, in period P31, the source RF signal HF is supplied as the power H4 to the upper electrode. In an embodiment, the power H4 may be 50 W to 2,000 W. As an example, the power H4 may be 200 W. In addition, in period P31, the bias RF signal MF is supplied as the power M2 to the lower electrode. In an embodiment, the power M2 may be 10 W to 100 W. As an example, the power M2 may be 50 W. In addition, in period P31, the bias RF signal LF is supplied as the power L1 to the lower electrode. As an example, the power L1 may be zero power.

Subsequently, in period P32, the source RF signal HF is supplied as the power H3 to the upper electrode. In an embodiment, the power H3 may be 20 W to 500 W. As an example, the power H3 may be 150 W. In addition, in period P32, the bias RF signal MF is supplied as the power M1 to the lower electrode. As an example, the power M1 may be zero power. In addition, in period P32, the bias RF signal LF is supplied as the power L1 to the lower electrode.

Subsequently, in period P33, the source RF signal HF is supplied as the power H1 to the upper electrode. As an example, the power H1 may be zero power. In addition, in period P33, the bias RF signal MF is supplied as the power M1 to the lower electrode. In addition, in period P33, the bias RF signal LF is supplied as the power L1 to the lower electrode.

Subsequently, in period P34, the source RF signal HF is supplied as the power H2 to the upper electrode. In an embodiment, the power H2 may be 20 W to 200 W. As an example, the power H2 may be 100 W. In addition, in period P34, the bias RF signal MF is supplied as the power M1 to the lower electrode. As an example, the power M1 may be zero power. In addition, in period P34, the bias RF signal LF is supplied as the power L2 to the lower electrode. In an embodiment, the power L2 may be 10 W to 150 W. As an example, the power L2 may be 75 W.

In the example shown in FIG. 11, periods P31 to P34 are repeated to generate plasma from the processing gas in step ST32. In this example, in periods P31 and P32, active species contributing to the etching the silicon oxide film SOF are generated by the source RF signal HF. In addition, in period P32, the power of the source RF signal HF and the power of the bias RF signal MF are reduced. In addition, in period 34, the active species generated in periods P31 and P32 are attracted into the substrate W by the bias RF signal LF and the silicon oxide film SOF is etched. In addition, the source RF signal HF is supplied as the power H2 to the upper electrode in the period P34 to maintain the plasma generated in periods P31 and P32.

In addition, in periods P31 and P32, active species for forming the protective film PF which will be described later may be generated by the source RF signal HF to form the protective film PF on the silicon nitride film SNF. In addition, by the bias RF signal MF, an amount of the active species for forming the protective film PF and/or a composition of the protective film PF may be controlled. As an example, at least a surface of the protective film PF may be modified by the active species generated by the bias RF signal MF.

In the example shown in FIG. 11, when periods P31 to P34 are repeated and the etching the silicon oxide film SOF proceeds, the top surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in period P31. The active species may be active species generated from a carbon-containing gas. In an embodiment, the protective film PF may be formed by forming active sites on the surface of the silicon nitride film SNF and adsorbing another active species to the active sites. The active sites and the active species may be the active species generated in periods P31 and P32.

In the example shown in FIG. 11, when the etching the silicon oxide film SOF further proceeds, the silicon oxide film SOF is further etched in the recess RC while the surface of the silicon nitride film SNF is protected by the protective film PF (see FIG. 15). As described above, the silicon oxide film SOF is selectively etched with respect to the silicon nitride film SNF.

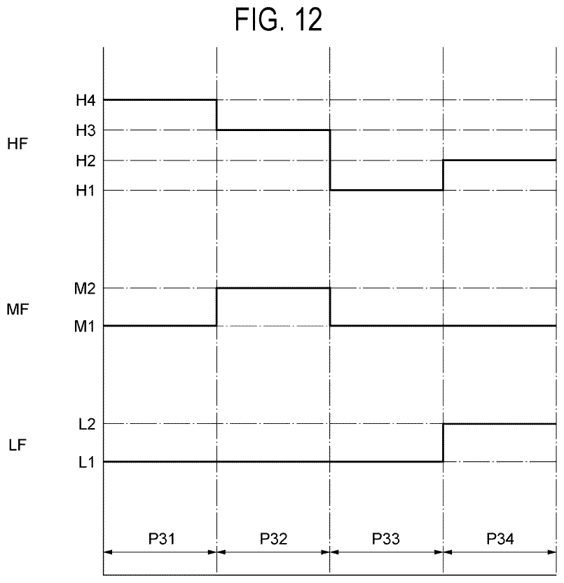

Next, an example shown in FIG. 12 will be described. In the example shown in FIG. 12, one cycle of step ST32 includes periods P31 to P34. First, in period P31, the source RF signal HF is supplied as the power H4 to the upper electrode. In an embodiment, the power H4 may be 50 W to 2,000 W. As an example, the power H4 may be 200 W. In addition, in period P31, the bias RF signal MF is supplied as the power M1 to the lower electrode. As an example, the power M1 may be zero power. In addition, in period P31, the bias RF signal LF is supplied as the power L1 to the lower electrode. As an example, the power L1 may be zero power.

Subsequently, in period P32, the source RF signal HF is supplied as the power H3 to the upper electrode. In an embodiment, the power H3 may be 20 W to 500 W. As an example, the power H3 may be 150 W. In addition, in period P32, the bias RF signal MF is supplied as the power M2 to the lower electrode. In an embodiment, the power M2 may be 10 W to 100 W. As an example, the power M2 may be 50 W. In addition, in period P32, the bias RF signal LF is supplied as the power L1 to the lower electrode.

Subsequently, in period P33, the source RF signal HF is supplied as the power H1 to the upper electrode. As an example, the power H1 may be zero power. In addition, in period P33, the bias RF signal MF is supplied as the power M1 to the lower electrode. In addition, in period P33, the bias RF signal LF is supplied as the power L1 to the lower electrode.

Subsequently, in period P34, the source RF signal HF is supplied as the power H2 to the upper electrode. In an embodiment, the power H2 may be 20 W to 200 W. As an example, the power H2 may be 100 W. In addition, in period P34, the bias RF signal MF is supplied as the power M1 to the lower electrode. As an example, the power M1 may be zero power. In addition, in period P34, the bias RF signal LF is supplied as the power L2 to the lower electrode. In an embodiment, the power L2 may be 10 W to 150 W. As an example, the power L2 may be 75 W.

In the example shown in FIG. 12, periods P31 to P34 are repeated and plasma is generated from the processing gas in step ST32. In this example, in periods P31 and P32, active species contributing to the etching the silicon oxide film SOF may be generated by the source RF signal HF. In addition, in period P32, the power of the source RF signal HF is reduced and the power of the bias RF signal MF is increased. In addition, in period P34, the active species generated in period P31 and P32 are attracted into the substrate W by the bias RF signal LF and the silicon oxide film SOF is etched. In addition, the source RF signal HF is supplied as the power H2 to the upper electrode in period P34 to maintain the plasma generated in periods P31 and P32.

In addition, in periods P31 and P32, active species for forming the protective film PF which will be described later may be generated by the source RF signal HF to form the protective film PF on the silicon nitride film SNF. In addition, by the bias RF signal MF, an amount of the active species for forming the protective film PF and/or a composition of the protective film PF may be controlled. As an example, at least a surface of the protective film PF may be modified by the active species generated by the bias RF signal MF.

In the example shown in FIG. 12, when periods P31 to P34 are repeated and the etching the silicon oxide film SOF proceeds, the top surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in period P31. The active species may be active species generated from a carbon-containing gas. In an embodiment, the protective film PF may be formed by forming active sites on the surface of the silicon nitride film SNF and adsorbing another active species to the active site. The active sites and the active species may be the active species generated in periods P31 and P32.

In the example shown in FIG. 12, when the etching the silicon oxide film SOF further proceeds, the silicon oxide film SOF is further etched in the recess RC while the surface of the silicon nitride film SNF is protected by the protective film PF (see FIG. 15). As described above, the silicon oxide film SOF is selectively etched with respect to the silicon nitride film SNF.

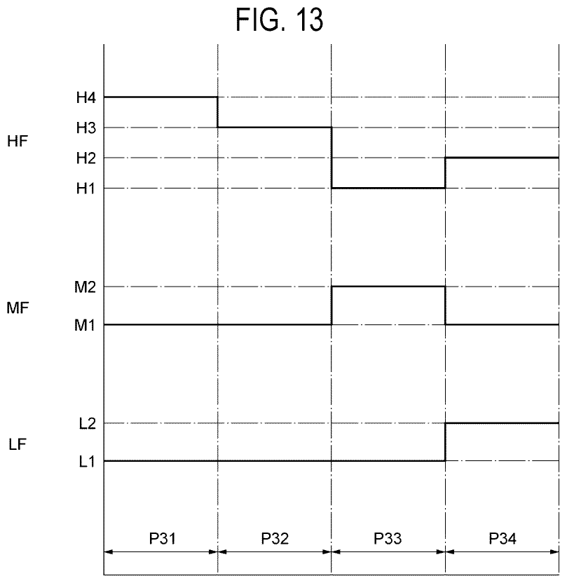

Next, an example shown in FIG. 13 will be described. In the example shown in FIG. 13, one cycle of step ST32 includes periods P31 to P34. First, in period P31, the source RF signal HF is supplied as the power H4 to the upper electrode. In an embodiment, the power H4 may be 50 W to 2,000 W. As an example, the power H4 may be 200 W. In addition, in period P31, the bias RF signal MF is supplied as the power M1 to the lower electrode. As an example, the power M1 may be zero power. In addition, in period P31, the bias RF signal LF is supplied as the power L1 to the lower electrode. As an example, the power L1 may be zero power.

Subsequently, in period P32, the source RF signal HF is supplied as the power H3 to the upper electrode. In an embodiment, the power H3 may be 20 W to 500 W. As an example, the power H3 may be 150 W. In addition, in period P32, the bias RF signal MF is supplied as the power M1 to the lower electrode. In addition, in period P32, the bias RF signal LF is supplied as the power L1 to the lower electrode.

Subsequently, in period P33, the source RF signal HF is supplied as the power H1 to the upper electrode. As an example, the power H1 may be zero power. In addition, in period P33, the bias RF signal MF is supplied as the power M2 to the lower electrode. In an embodiment, the power M2 may be 10 W to 100 W. As an example, the power M2 may be 50 W. In addition, in period P33, the bias RF signal LF is supplied as the power L1 to the lower electrode.

Subsequently, in period P34, the source RF signal HF is supplied as the power H2 to the upper electrode. In an embodiment, the power H2 may be 20 W to 200 W. As an example, the power H2 may be 100 W. In addition, in period P34, the bias RF signal MF is supplied as the power M1 to the lower electrode. As an example, the power M1 may be zero power. In addition, in period P34, the bias RF signal LF is supplied as the power L2 to the lower electrode. In an example, the power L2 may be 10 W to 150 W. As an example, the power L2 may be 75 W.

In the example shown in FIG. 13, periods P31 to P34 are repeated and plasma is generated from the processing gas in step ST32. In this example, in period P31 and P32, active species contributing to the etching the silicon oxide film SOF may be generated by the source RF signal HF. In addition, in period P32, the power of the source RF signal HF is reduced. In addition, in period P34, the active species generated in periods P31 and P32 are attracted into the substrate W by the bias RF signal LF and the silicon oxide film SOF is etched. In addition, the source RF signal HF is supplied as the power H2 to the upper electrode in period P34 to maintain the plasma generated in periods P31, P32, and/or P33.

In addition, in periods P31, P32, and/or P33, active species for forming the protective film PF which will be described later may be generated by the source RF signal HF to form the protective film PF on the silicon nitride film SNF. In addition, by the bias RF signal MF, an amount of the active species for forming the protective film PF and/or a composition of the protective film PF may be controlled. As an example, at least a surface of the protective film PF may be modified by the active species generated by the bias RF signal MF.

In the example shown in FIG. 13, when periods P31 to P34 are repeated and the etching the silicon oxide film SOF proceeds, the top surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in period P31. The active species may be active species generated from a carbon-containing gas. In an embodiment, the protective film PF may be formed by forming active sites on the surface of the silicon nitride film SNF and adsorbing another active species to the active sites. The active sites and the active species may be the active species generated in periods P31 and P32.

In the example shown in FIG. 13, when the etching the silicon oxide film SOF further proceeds, the silicon oxide film SOF is also etched in the recess RC while the surface of the silicon nitride film SNF is protected by the protective film PF (see FIG. 15). As described above, the silicon oxide film SOF is selectively etched with respect to the silicon nitride film SNF.

In an exemplary embodiment of the present disclosure, by plasma generated from a processing gas including a gas containing tungsten and fluorine and a gas capturing active species including fluorine, a film as an etching target (e.g., the silicon oxide film SOF) is selectively etched with respect to a film containing silicon and nitrogen (e.g., the silicon nitride film SNF). Thus, in the etching, the active species including fluorine, which are generated from the gas containing tungsten and fluorine, are captured by the gas capturing the active species including fluorine. Accordingly, in the etching, it is possible to suppress the active species including fluorine from reacting with the film containing silicon and nitrogen. Therefore, in the etching, it is possible to improve selectivity of the film containing silicon and nitrogen with respect to the film as the etching target.

The present disclosure may include, for example, the following configurations.

### (Supplementary Note 1)

An etching method performed in a plasma processing apparatus including a chamber, including:
(a) preparing a substrate on a substrate support disposed in the chamber, wherein the substrate includes a plurality of first regions and at least one second region between the first regions in a plan view of the substrate, wherein the substrate includes a first film including silicon and nitrogen, wherein the first film is disposed in the plurality of first regions and includes a recess in the at least one second region, and a second film is disposed in the recess;
(b) supplying a processing gas, which includes a first gas including metal and fluorine and a second gas capturing active species including fluorine, into the chamber; and
(c) while (b) is performed, selectively etching the second film with respect to the first film in at least the recess by generating plasma from the processing gas by using a source radio frequency (RF) signal having a first frequency.

### (Supplementary Note 2)

The etching method of Supplementary Note 1, wherein in (a), the second film is further disposed on the first film, the substrate further includes a mask including a first opening and disposed on the second film, and the mask is disposed on the second film such that the first opening overlaps with the recess in a plan view of the substrate.

### (Supplementary Note 3)

The etching method of Supplementary Note 2, wherein in (a), the mask includes a second opening having an opening area larger than that of the first opening, the mask is disposed on the second film such that the second opening overlaps with the recess in a plan view of the substrate, and the number of the recess overlapping with the first opening is smaller than that of the recess overlapping with the second opening.

### (Supplementary Note 4)

The etching method of any one of Supplementary Notes 1 to 3, wherein the second film is a film including silicon and oxygen.

### (Supplementary Note 5)

The etching method of any one of Supplementary Notes 1 to 4, wherein the first gas is a tungsten-containing gas or a molybdenum-containing gas.

### (Supplementary Note 6)

The etching method of any one of Supplementary Notes 1 to 5, wherein the second gas is a hydrogen-containing gas.

### (Supplementary Note 7)

The etching method of Supplementary Note 6), wherein the hydrogen-containing gas is hydrogen gas.

### (Supplementary Note 8)

The etching method of any one of Supplementary Notes 1 to 5, wherein the second gas is carbon monoxide gas.

### (Supplementary Note 9)

The etching method of any one of Supplementary Notes 1 to 8, wherein the processing gas further includes a carbon-containing gas.

### (Supplementary Note 10)

The etching method of Supplementary Note 9), wherein the carbon-containing gas is a fluorocarbon gas.

### (Supplementary Note 11)

The etching method of Supplementary Note 9, wherein the carbon-containing gas is a hydrofluorocarbon gas.

### (Supplementary Note 12)

The etching method of any one of Supplementary Notes 1 to 11, wherein (c) includes:
(c1) generating the plasma by setting power of the source RF signal as a first power, and supplying a first bias signal as a second power to the substrate support; and
(c2) after (c1), supplying the first bias signal as a third power higher than the second power to the substrate support.

In addition, an example of each power is as follows.
First power: the power H4
Second power: the power L1
Third power: the power L2

### (Supplementary Note 13)

The etching method of Supplementary Note 12, wherein the (c2) further includes setting the power of the source RF signal as a fourth power lower than the first power.

In addition, examples of the fourth power include the powers H1, H₂, and/or H3.

(Supplementary Note 14) The etching method of Supplementary Note 13, wherein the fourth power is zero power.

### (Supplementary Note 15)

The etching method of Supplementary Note 12, wherein the second power is zero power.

### (Supplementary Note 16)

The etching method of Supplementary Note 12, wherein in (c1), a second bias RF signal having a second frequency lower than the first frequency is supplied as a fifth power to the substrate support, and
wherein in (c2), the second bias RF signal is supplied as a sixth power lower than the fifth power to the substrate support.

In addition, an example of each power is as follows.
Fifth power: the power M2
Sixth power: the power M1

### (Supplementary Note 17)

The etching method of any one of Supplementary Notes 1 to 16, wherein the first frequency of the source RF signal is 60 MHz to 200 MHz.

### (Supplementary Note 18)

The etching method of any one of Supplementary Notes 1 to 16, wherein a frequency of the first bias signal is a frequency not substantially contributing to the generation of the plasma.

### (Supplementary Note 19)

The etching method of Supplementary Note 18, wherein the frequency of the first bias signal is 100 kHz to 800 kHz.

### (Supplementary Note 20)

The etching method of Supplementary Note 16, wherein the second frequency of the second bias RF signal is 3 MHz to 40 MHz.

### (Supplementary Note 21)

An etching method performed in a plasma processing apparatus including a chamber, including:
(a) preparing a substrate on a substrate support disposed in the chamber, wherein the substrate includes a plurality of first regions and at least one second region between the first regions in a plan view of the substrate, wherein the substrate includes a first film including at least one selected from the group consisting of a SiN film, a SiON film, a SiC film, a SiOC film, and a boron nitride film, wherein the first film is disposed in the plurality of first regions and includes a recess in the at least one second region, and wherein a second film is disposed in the recess;
(b) supplying a processing gas, which includes a first gas including metal and fluorine and a second gas capturing active species including fluorine, into the chamber; and
(c) while (b) is performed, selectively etching the second film with respect to the first film in at least the recess by generating plasma from the processing gas by using a source radio frequency (RF) signal having a first frequency.

### (Supplementary Note 22)

A plasma processing apparatus including:
a chamber; and
a controller,
wherein the controller performs controls to execute:
   (a) preparing a substrate on a substrate support disposed in the chamber, wherein the substrate includes a plurality of first regions and at least one second region between the first regions in a plan view of the substrate, wherein the substrate includes a first film including silicon and nitrogen, wherein the first film is disposed in the plurality of first regions and includes a recess in the at least one second region, and wherein a second film is disposed in the recess;
   (b) supplying a processing gas, which includes a first gas including metal and fluorine and a second gas capturing fluorine radicals, into the chamber; and
   (c) while (b) is performed, etching the second film in at least the recess by generating plasma from the processing gas by using a source radio frequency (RF) signal having a first frequency.

According to the present disclosure in some embodiments, it is possible to provide an etching technique capable of improving a selectivity.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An etching method performed in a plasma processing apparatus including a chamber, comprising:
(a) preparing a substrate on a substrate support disposed in the chamber, wherein the substrate includes a plurality of first regions and at least one second region disposed between the first regions in a plan view of the substrate, wherein the substrate includes a first film containing silicon and nitrogen, wherein the first film is disposed in the plurality of first regions and includes a recess in the at least one second region, and wherein a second film is disposed in the recess;
(b) supplying a processing gas, which includes a first gas including metal and fluorine and a second gas capturing active species including fluorine, into the chamber; and
(c) while (b) is performed, selectively etching the second film with respect to the first film in at least the recess by generating plasma from the processing gas by using a source radio frequency (RF) signal having a first frequency.

2. The etching method of claim 1, wherein, in (a), the second film is further disposed on the first film, the substrate further includes a mask including a first opening and disposed on the second film, and, the mask is disposed on the second film such that the first opening overlaps with the recess in a plan view of the substrate.

3. The etching method of claim 2, wherein in (a), the mask includes a second opening having an opening area larger than that of the first opening, the mask is disposed on the second film such that the second opening overlaps with the recess in a plan view of the substrate, and the number of the recess overlapping with the first opening is smaller than that of the recess overlapping with the second opening.

4. The etching method of claim 1, wherein the second film is a film including silicon and oxygen.

5. The etching method of claim 1, wherein the first gas is a tungsten-containing gas or a molybdenum-containing gas.

6. The etching method of claim 1, wherein the second gas is a hydrogen-containing gas.

7. The etching method of claim 6, wherein the hydrogen-containing gas is hydrogen gas.

8. The etching method of claim 1, wherein the second gas is carbon monoxide gas.

9. The etching method of claim 1, wherein the processing gas further includes a carbon-containing gas.

10. The etching method of claim 9, wherein the carbon-containing gas is a fluorocarbon gas.

11. The etching method of claim 9, wherein the carbon-containing gas is a hydrofluorocarbon gas.

12. The etching method of claim 1, wherein (c) further comprises:
(c1) generating the plasma by setting power of the source RF signal as a first power, and supplying a first bias signal as a second power to the substrate support; and
(c2) after (c1), supplying the first bias signal as a third power higher than the second power to the substrate support.

13. The etching method of claim 12, wherein (c2) further includes setting the power of the source RF signal as a fourth power lower than the first power.

14. The etching method of claim 13, wherein the fourth power is zero power.

15. The etching method of claim 12, wherein the second power is zero power.

16. The etching method of claim 12, wherein in (c1), a second bias RF signal having a second frequency lower than the first frequency is supplied as a fifth power to the substrate support, and
wherein in (c2), the second bias RF signal is supplied as a sixth power lower than the fifth power to the substrate support.

17. The etching method of claim 1, wherein the first frequency of the source RF signal is 60 MHz to 200 MHz.

18. The etching method of claim 12, wherein a frequency of the first bias signal is a frequency not substantially contributing to the generation of the plasma.

19. The etching method of claim 18, wherein the frequency of the first bias signal is 100 kHz to 800 kHz.

20. The etching method of claim 16, wherein the second frequency of the second bias RF signal is 3 MHz to 40 MHz.

21. An etching method performed in a plasma processing apparatus including a chamber, comprising:
(a) preparing a substrate on a substrate support disposed in the chamber, wherein the substrate includes a plurality of first regions and at least one second region between the first regions in a plan view of the substrate, wherein the substrate includes a first film including at least one selected from the group consisting of a SiN film, a SiON film, a SiC film, a SiOC film, and a boron nitride film, wherein the first film is disposed in the plurality of first regions and includes a recess in the at least one second region, and wherein a second film is disposed in the recess;
(b) supplying a processing gas, which includes a first gas including metal and fluorine and a second gas capturing active species including fluorine, into the chamber; and
(c) while (b) is performed, selectively etching the second film with respect to the first film in at least the recess by generating plasma from the processing gas by using a source radio frequency (RF) signal having a first frequency.

22. A plasma processing apparatus comprising:
a chamber; and
a controller,
wherein the controller performs controls to execute:
(a) preparing a substrate on a substrate support disposed in the chamber, wherein the substrate includes a plurality of first regions and at least one second region between the first regions in a plan view of the substrate, wherein the substrate includes a first film including silicon and nitrogen, wherein the first film is disposed in the plurality of first regions and includes a recess in the at least one second region, and wherein a second film is disposed in the recess;
(b) supplying a processing gas, which includes a first gas including metal and fluorine and a second gas capturing fluorine radicals, into the chamber; and
(c) while (b) is performed, etching the second film in at least the recess by generating plasma from the processing gas by using a source radio frequency (RF) signal having a first frequency.
